(19) United States
(12) Patent Application Publication
(10) Pub. No.: US 2016/0056327 A1
(43) Pub. Date: Feb. 25, 2016

(54) NITRIDE LIGHT EMITTING ELEMENT AND METHOD FOR MANUFACTURING THE SAME

(71) Applicant: USHIO DENKI KABUSHIKI KAISHA, Tokyo (JP)

(72) Inventors: Toru SUGIYAMA, Hyogo (JP); Masashi TSUKIHARA, Hyogo (JP); Kohei MIYOSHI, Hyogo (JP)

(73) Assignee: USHIO DENKI KABUSHIKI KAISHA, Tokyo (JP)

(21) Appl. No.: 14/781,271

(22) PCT Filed: Mar. 24, 2014
(86) PCT No.: PCT/JP2014/058042

§ 371 Date: Sep. 29, 2015

(30) Foreign Application Priority Data
Mar. 29, 2013 (JP) 2013-073952

(51) Int. Cl. H01L 33/02; H01L 33/32; H01L 33/00; H01L 33/06

(52) U.S. Cl. CPC H01L 33/025; H01L 33/06; H01L 33/32; H01L 33/0095; H01L 33/007

(57) ABSTRACT

Provided is a nitride light emitting element which achieves a high light extraction efficiency even at a low operation voltage and which can be manufactured by means of a simple process. A nitride light emitting element 1 has, on a support substrate 11, an n-type layer 35, a p-type layer 31, and a light emitting layer 33 formed at a position interposed between the n-type layer 35 and the p-type layer 31. The n-type layer 35 is constituted of AlₓGa₁₋ₓN (0<x≦1) having a carrier concentration higher than the dopant Si concentration.

### TECHNICAL FIELD

The present invention relates to a nitride light emitting element and a method for manufacturing the same.

### BACKGROUND ART

A nitride semiconductor element formed from nitride of a group III element such as Al, Ga, or In is used as a light emitting element by interposing a light emitting layer between an electron supply layer made of an n-type semiconductor and a hole supply layer made of a p-type semiconductor. More specifically, by applying a voltage between the n-type semiconductor layer and the p-type semiconductor layer to let an electric current flow through the light emitting layer, the region is made to emit light.

Here, when a resistance value between a stacked body of the n-type semiconductor layer, the light emitting layer, and the p-type semiconductor layer (hereafter referred to as “LED layer” herein) and an electrode stacked, for example, on top of the n-type semiconductor layer (hereafter referred to as “n-side electrode”) is high, the voltage needed for allowing an electric current, which is needed for light emission, to flow becomes high, leading to decrease in the efficiency. For this reason, in order to extract light having a large light quantity at a low operation voltage, it is important to reduce the resistance value between the LED layer and the n-side electrode as much as possible.

In view of such a problem, the following Patent Document 1 discloses an LED element in which the n-type semiconductor layer is formed by successive stacking of a high-concentration-type layer doped with an n-type impurity such as Si at a high concentration and a low-concentration-type layer doped with an n-type impurity at a concentration lower than that of this high-concentration-type layer.

### PRIOR ART DOCUMENTS

### Patent Documents

Patent Document 1: JP-A-2007-258529

### Non-Patent Document

Non-patent Document 1: S. Fritze, et al., “High Si and Ge n-type doping of GaN doping—Limits and impact on stress”, Applied Physics Letters 100, 122104, (2012) Non-patent Document 2: Yaho, et al., “n-type Conductivity Control of Si-doped AlN and high-Al-composition AlGaN”, Technical Research Report of The Institute of Electronics, Information and Communication Engineers, 102(114), 61-64, 2002-06-06

### SUMMARY OF THE INVENTION

### Problems to be Solved by the Invention

In order to let the needed electric current flow through the light emitting layer at an operation voltage as low as possible, it is preferable to reduce the element resistance as much as possible. For this purpose, there can be conceived a method of achieving an ohmic connection between the n-type layer and the n-side electrode by increasing the Si-doping amount into the n-type semiconductor layer as much as possible.

Here, in achieving a blue LED as the nitride light emitting element, GaN is generally used as the n-type semiconductor layer. However, there is known a phenomenon such that, when the concentration of an n-type dopant that is injected into this GaN-type layer is increased to be 1×10¹⁹/cm³ or more, a film roughening is generated due to aggravation of the atomic bonding state or the like (See, for example, the above Non-patent Document 1). When such a phenomenon occurs, an n-type layer having a low resistance is not formed, and eventually the light emission efficiency decreases.

In order to overcome this problem, the above Patent Document 1 adopts a construction in which an n-type layer having a high concentration and an n-type layer having a low concentration are successively alternately stacked. According to this Patent Document 1, it is assumed that, by adopting such a construction, the surface roughening formed on the high-concentration-type layer is covered with the low-concentration-type layer, whereby an n-type layer having a good quality is formed.

However, when the method disclosed in the Patent Document 1 is adopted, there is a need to stack plural sets of a high-concentration-type layer and a low-concentration-type layer successively alternately as the n- type layer, thereby raising another problem of making the process complex.

By increasing the carrier concentration of the n-type layer, the resistance of the n- type layer can be reduced. For this purpose, it has been generally considered necessary to increase the Si-doping concentration as much as possible. For example, the above Non-patent Document 2 discloses that, when the dopant Si concentration is increased, the carrier concentration increases to a certain degree in accordance therewith; however, when the carrier concentration exceeds a certain threshold value, the increase of the carrier concentration is saturated, and that the carrier concentration is lower than the Si concentration.

In the meantime, when the n-type layer is achieved with GaN, the problem of film roughening occurs as described above, so that the Si concentration cannot be increased to be 1×10¹⁹/cm³ or more and, as a result of this, it has been considered that there is a limit in reducing the resistance of the n-type layer by increasing the carrier concentration.

By eager researches, the present inventors have found out that, by constructing the n-type layer with AlₓGa₁₋ₓN (0<x≦1) grown under certain conditions, the resistance can be reduced to be lower than that of a conventional case by a simple process, thereby arriving at the present invention. In other words, an object of the present invention is to provide, by means of a nitride light emitting element containing an n-type layer such as this, an element which achieves a high light extraction efficiency even at a low operation voltage and which can be manufactured by a simple process.

### Means for Solving the Problems

A nitride light emitting element of the present invention is a nitride light emitting element having, on a support substrate, an n-type layer, a p-type layer, and a light emitting layer formed at a position interposed between the n- type layer and the p-type layer, wherein the n-type layer is constituted of AlₓGa₁₋ₓN (0<x≦1) having a carrier concentration higher than a dopant Si concentration thereof.

By eager researches, the present inventors have found out that, when the n-type layer is constituted of AlₓGa₁₋ₓN (0<x≦1) instead of GaN, the carrier concentration becomes higher than the dopant Si concentration by growing the n-type layer under predetermined conditions.

In greater detail, the conditions for growing the n-type layer are set in such a manner that the crystal is grown by supplying, into a processing furnace, a source material gas in which a V/III ratio, which is a ratio of a flow rate of a compound containing a group V element to a flow rate of a compound containing a group III element, is larger than 2000 and not larger than 10000. When the n-type layer is grown by this method, the n-type layer in which the carrier concentration is higher than the dopant Si concentration is formed.

According to the nitride light emitting element containing this n-type layer, the carrier concentration higher than the dopant Si concentration is achieved, so that the resistance of the n-type layer can be reduced even when the Si concentration is not increased to be an extremely high value. This allows that the amount of electric current needed for light emission can be let to flow through the light emitting layer even at a low operation voltage, thereby improving the light emission efficiency.

Further, in achieving the above construction, it is sufficient that the V/III ratio of the source material gas for crystal growth of the n-type layer is set to be within a range larger than 2000 and not larger than 10000, so that the process itself is not rendered complex as compared with the conventional case. Therefore, the nitride light emitting element can be manufactured by means of a simple process without the need for a complicated manufacturing process.

Here, in the above construction, the n-type layer may be constituted of AlₓGa₁₋ₓN (0<x≦1) having the dopant Si concentration not lower than 1×10¹⁹/cm³.

By eager researches of the present inventors, it has been confirmed that, when the n-type layer is constituted of AlₓGa₁₋ₓN (0<x≦1) instead of GaN, the problem of film roughening does not occur even when the dopant Si concentration is set to be not lower than 1×10¹⁹/cm³, or further, not lower than 7×10¹⁹/cm³.

In other words, as compared with a conventional case, the Si concentration can be increased by setting the concentration of Si, with which the n-type layer constituted of AlₓGa₁₋ₓN (0<x≦1) is doped, to be a value not lower than 1×10¹⁹/cm³ which is an upper limit value at which the film roughening does not occur in GaN. Further, the carrier concentration of this n-type layer is achieved to be higher than the dopant Si concentration. For this reason, the resistance of the n-type layer can be extremely

### Effect of the Invention

According to the nitride light emitting element of the present invention, the resistance value of the n-type layer can be reduced, so that, by means of a simple process, the amount of electric current needed for light emission can be let to flow through the light emitting layer even at a low operation voltage, thereby improving the light emission efficiency.

### BRIEF DESCRIPTION OF THE DRAWINGS

FIG. 1 is a schematic sectional view showing one embodiment of a nitride light emitting element.

FIG. 2A is a photograph of an AlₓGa₁₋ₓN (0<x≦1) layer surface when the Si concentration is set to be 7×10¹⁹/cm³.

FIG. 2B is a photograph of a GaN-type layer surface when the Si concentration is set to be 1.5×10¹⁹/cm³.

FIG. 3 is a view of construction of a verification element for verifying a relationship between the Si concentration and the carrier concentration.

FIG. 4 is a graph showing a relationship of the V/III ratio to the Si concentration and the carrier concentration of the n-type layer of the verification element when the verification element is fabricated while changing the V/III ratio.

FIG. 5 is a view of construction of a verification element for verifying the I-V characteristics and the light emitting characteristics.

FIG. 6 is a graph showing a relationship of electric current-light emission output when an electric current is applied to each verification element with differing V/III ratio at the time of forming the n-type layer.

FIG. 7 is a graph showing the I-V characteristics when a voltage is applied to each verification element with differing V/III ratio at the time of forming the n-type layer.

FIG. 8 is a sectional TEM photograph of the n-type layer in five kinds of verification elements in which the n-type layer has been grown while setting the V/III ratio to be 2000, 4000, 8000, 10000, and 12000.

FIG. 9 is a schematic sectional view showing another embodiment of a nitride light emitting element.

### MODE FOR CARRYING OUT THE INVENTION

A nitride light emitting element and a method for manufacturing the same according to the present invention will be described with reference to the drawings. Here, in each of the Figures, the dimension ratio in the Figures does not necessarily coincide with the actual dimension ratio.

### [Structure]

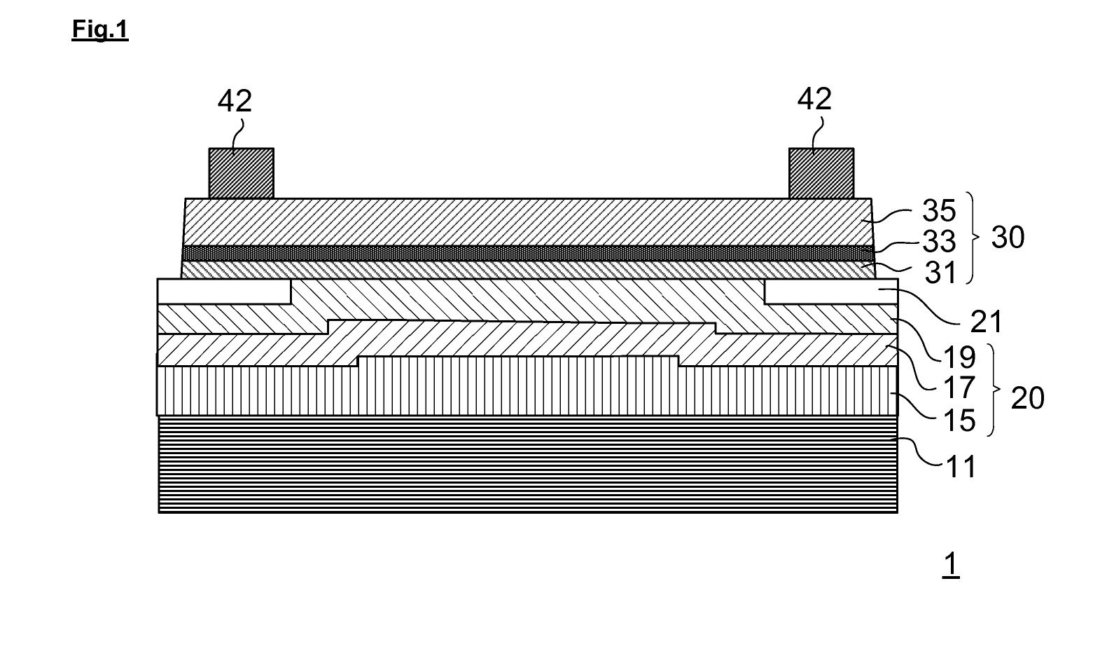

One example of a structure of a nitride light emitting element according to the present invention will be described with reference to FIG. 1. FIG. 1 is a schematic sectional view of one embodiment of the nitride light emitting element.

A nitride light emitting element 1 is constructed to include a support substrate 11, an electroconductive layer 20, an insulating layer 21, an LED layer 30, and a power supply terminal 42. The LED layer 30 is formed in such a manner that a p-type layer 31, a light emitting layer 33, and an n-type layer 35 are stacked in this order from below.

(Support substrate 11)

The support substrate 11 is constituted, for example, of an electroconductive substrate such as CuW, W, or Mo or a semiconductor substrate such as Si.

(Electroconductive layer 20)

An electroconductive layer 20 made of a multilayer structure is formed on top of the support substrate 11. In the present embodiment, this electroconductive layer 20 includes a solder layer 15, a protective layer 17, and a reflection electrode 19.

The solder layer 15 is constituted, for example, of Au—Sn, Au—In, Au—Cu—Sn, Cu—Sn, Pd—Sn, Sn, or the like. As will be described later in the section of the manufacturing method, the solder layer 15 is used in bonding the sapphire substrate and the support substrate 11 with each other (See the step S5).

The protective layer 17 is constituted, for example, of a Pt-based metal (alloy of Ti and Pt), W, Mo, Ni, or the like. As will be described later, the protective layer 17 functions to prevent decrease in the light emission efficiency due to dropping of the reflectivity by diffusion of the material constituting the solder to the later-described reflection electrode 19 side in bonding the two substrates with each other via the solder layer at the time of processing.

The reflection electrode 19 is constituted, for example, of an Ag-based metal (alloy of Ni and Ag), Al, Rh, or the like. In the nitride light emitting element 1, it is assumed that the light radiated from the light emitting layer 33 of the LED layer 30 is extracted in an upward direction (to the n-type layer 35 side) as viewed on a paper sheet of FIG. 1, and the reflection electrode 19 functions to enhance the light emission efficiency by reflecting the light, which is radiated downward from the light emitting layer 33, in the upward direction.

Here, a part of the electroconductive layer 20 is in contact with the LED layer 30, more specifically, with the p-type layer 31. When a voltage is applied between the support substrate 11 and the power supply terminal 42, an electric current path in which the electric current flows to the power supply terminal 42 via the support substrate 11, the electroconductive layer 20, and the LED layer 30 is formed.

(Insulating layer 21)

The insulating layer 21 is constituted, for example, of SiO₂, SiN, Zr₂O₃, AlN, Al₂O₃, or the like. An upper surface of this insulating layer 21 is in contact with a bottom surface of the p-type layer 31. Here, as will be described later, this insulating layer 21 functions as an etching stopper layer at the time of element separation and also functions to widen the electric current in a direction parallel to the substrate surface of the support substrate 11.

(LED layer 30)

As described above, the LED layer 30 is formed in such a manner that the p-type layer 31, the light emitting layer 33, and the n-type layer 35 are stacked in this order from below.

The p-type layer 31 is constituted, for example, of a multilayer structure that includes a layer constituted of AlₓGa₁₋ₓN (0<y≦1) (hole supply layer) and a layer constituted of GaN (protective layer). Each layer is doped with a p-type impurity such as Mg, Be, Zn, or C.

The light emitting layer 33 is formed, for example, of a semiconductor layer having a multiquantum well structure in which a well layer made of InGaN and a barrier layer made of AlGaN are repeated. These layers may be undoped or may be doped to be of p-type or n-type.

The n-type layer 35 has a multilayer structure that includes a layer constituted of GaN (protective layer) in a region that is in contact with the light emitting layer 33 and includes a layer constituted of AlₓGa₁₋ₓN (0<x≦1) (electron supply layer) on top thereof. At least the protective layer is doped with an n-type impurity such as Si, Ge, S, Se, Sn, or Te, and is preferably doped with Si. Here, it is possible to adopt a construction in which the n-type layer 35 is formed only of an electron supply layer constituted of AlₓGa₁₋ₓN (0<x≦1).

Also, the n-type layer 35 constituted of AlₓGa₁₋ₓN (0<x≦1) is constructed in such a manner that the carrier concentration is higher than the dopant Si concentration. A method of achieving such a structure will be described later.

Further, in the present embodiment, this n-type layer 35 is constructed in such a manner that the dopant Si concentration is not lower than 1×10¹⁹/cm³. As will be described later on the basis of photographs obtained by experiments, in the present construction, film roughening does not occur even if the impurity concentration of the n-type layer 35 is set to be a value larger than 1×10¹⁹/cm³.

### (Power Supply Terminal 42)

The power supply terminal 42 is formed on top of the n-type layer 35 and is constituted, for example, of Cr—Au. To this power supply terminal 42, a wire constituted, for example, of Au, Cu, or the like (not illustrated in the drawings) is connected, and the other end of this wire is connected to a power supply pattern or the like of a substrate (not illustrated in the drawings) where the nitride light emitting element 1 is placed.

Here, although not illustrated in the drawings, an insulating layer serving as a protective film may be formed on a side surface and on an upper surface of the LED layer 30. Here, this insulating layer serving as the protective film is preferably constituted of a material having a light-transmitting property (for example, SiO₂ or the like).

In the above-described embodiment, one material constituting the p-type layer 31 is denoted as AlₓGa₁₋ₓN (0<y≦1), and one material constituting the n-type layer 35 is denoted as AlₓGa₁₋ₓN (0<x≦1); however, these may be the same material.

### [Verification of Presence or Absence of Film Roughening]

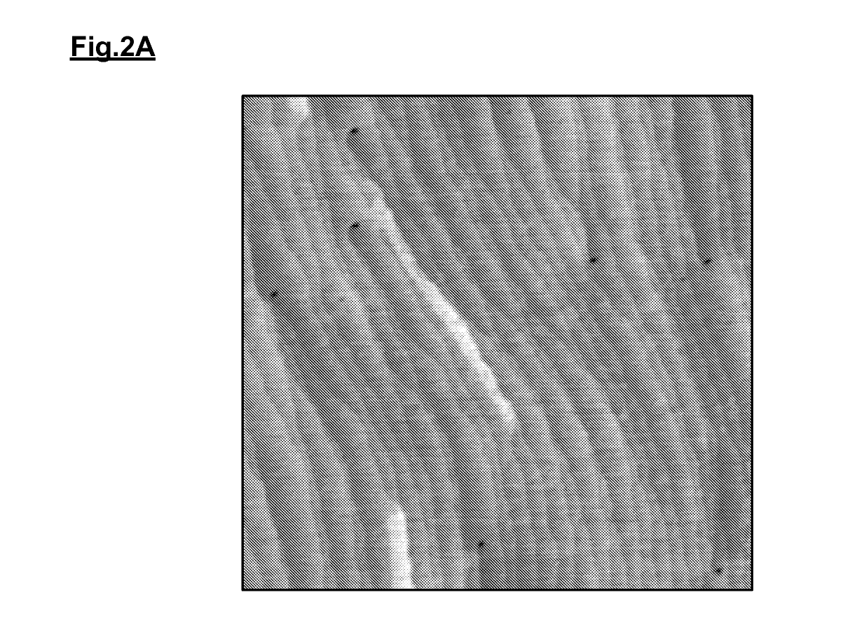

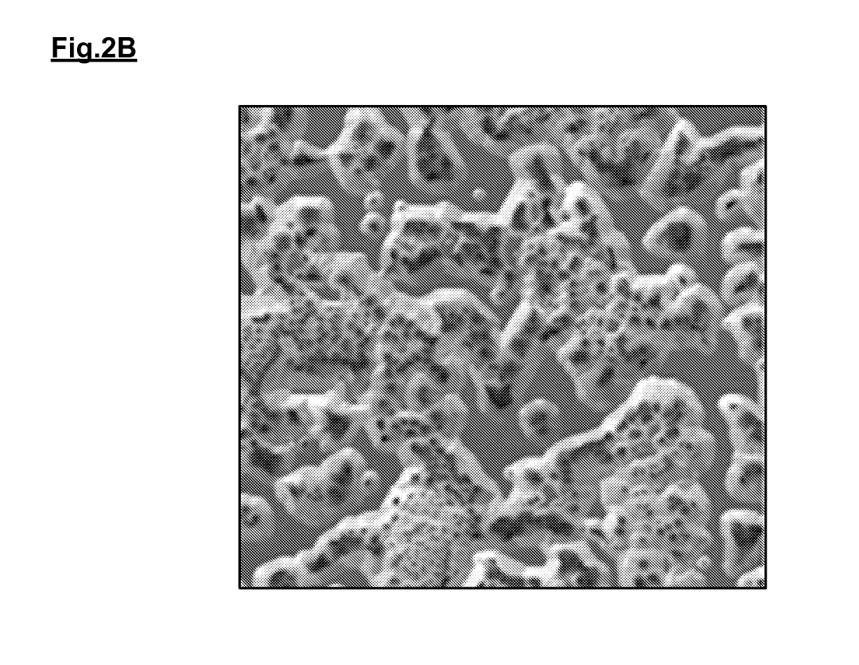

Next, with reference to experimental data of FIGS. 2A and 2B, description will be given on a fact that, by constructing the n-type layer 35 with AlₓGa₁₋ₓN (0<x≦1) as in the nitride light emitting element 1, film roughening is not generated even if the dopant Si concentration is set to be larger than 1×10¹⁹/cm³. Here, in the following, AlₓGa₁₋ₓN (0<x≦1) will be abbreviated as AlₓGa₁₋ₓN.

FIG. 2A is a photograph of an AlₓGa₁₋ₓN-type layer surface when the Si concentration is set to be 7×10¹⁹/cm³. Also, FIG. 2B is a photograph of a GaN-type layer surface when the Si concentration is set to be 1.5×10¹⁹/cm³. Here, FIG. 2A shows an image captured by AFM (Atomic Force Microscopy: interatomic force microscope), and FIG. 2B shows an image captured by SEM (Scanning Electron Microscope: scanning-type electron microscope).

Referring to FIG. 2B, it will be understood that, when the n-type layer is constituted of GaN, roughening is generated on the surface when the Si concentration is set to be 1.5×10¹⁹/cm³. Here, roughening on the surface could be confirmed in a similar manner when the impurity concentration was set to be 1.3×10¹⁹/cm³ or 2.0×10¹⁹/cm³. From this, it will be understood that, with respect to GaN, roughening is generated on the layer surface when the impurity concentration is set to be larger than 1×10¹⁹/cm³ as described in the Non-patent Document 1.

In contrast, from FIG. 2A, it will be understood that, when the n-type layer is constituted of AlₓGa₁₋ₓN, a step-like surface (atomic step) is confirmed and roughening is not generated on the layer surface even when the Si concentration is set to be 7×10¹⁹/cm³. Here, a photograph similar to that of FIG. 2A has been obtained when the Si concentration is set to be 2×10²⁰/cm³. Also, it has been confirmed that, in a similar manner, roughening is not generated on the layer surface even when the component ratio of Al and Ga is changed (AlₓGa₁₋ₓN) as constituent materials.

On the other hand, a photograph similar to that of FIG. 2A has been obtained when the n-type layer is constituted of GaN and the Si concentration is set to be 0.5×10¹⁹/cm³, that is, when the Si concentration is set to be not larger than 1×10¹⁹/cm³.

From the above, it will be understood that, by constructing the n-type layer with AlₓGa₁₋ₓN, the problem of film roughening does not occur even when the Si concentration is set to be larger than 1×10¹⁹/cm³.

### [Verification of Relationship Between Si Concentration and Carrier Concentration]

Next, with reference to data, description will be given on a fact that, through achieving the n-type layer 35 by a later-described method, the carrier concentration can be made higher than the concentration of Si with which the n-type layer 35 is doped.

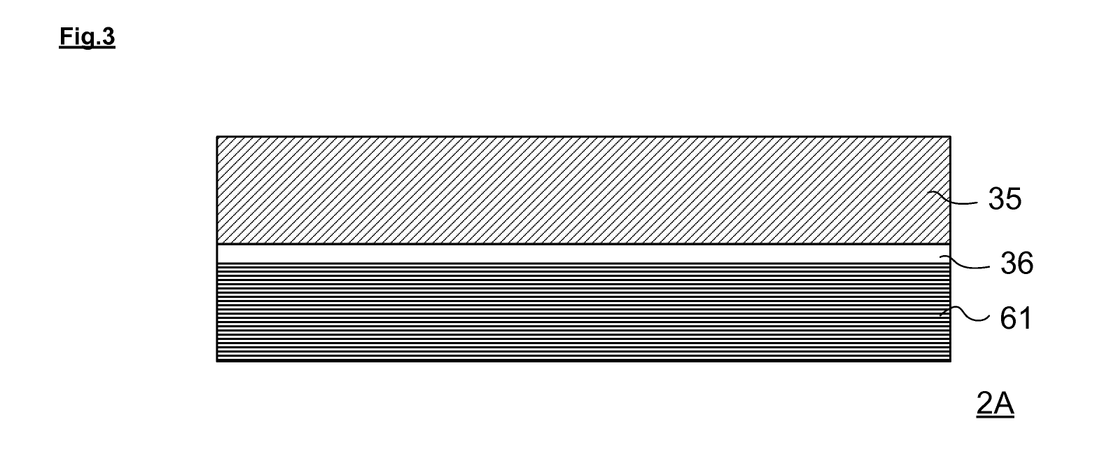

FIG. 3 shows an example of an element used for verification of the relationship between the Si concentration and the carrier concentration. The element 2A shown in FIG. 3 is an element for verification of the relationship between the Si concentration and the carrier concentration of the n-type layer 35 when, in the case of constructing the n-type layer 35 with AlₓGa₁₋ₓN, the conditions for growth of the AlₓGa₁₋ₓN is changed. For this reason, unlike the nitride light emitting element 1, the element was constructed within a range needed for verification.

The verification element 2A shown in FIG. 3 is constructed in such a manner that the n-type layer 35 constituted of AlₓGa₁₋ₓN is formed via an undoped layer 36 on top of a sapphire substrate 61.

In forming the n-type layer 35 constituted of AlₓGa₁₋ₓN, crystals of AlₓGa₁₋ₓN must be grown on an upper surface of the undoped layer 36. Generally, crystal growth is carried out by supplying a predetermined source material gas into an apparatus such as an MOCVD (Metal Organic Chemical Vapor Deposition: organic metal chemical gas-phase vapor deposition) apparatus under conditions with a predetermined temperature and a predetermined pressure.

In growing crystals of AlₓGa₁₋ₓN, a mixed gas containing TMG (trimethylgallium), TMA (trimethylaluminum), and ammonia is used as the source material gas. Further, in the case of doping with Si, TES (tetraethylsilane) is also supplied. Here, a plurality of verification elements 2A were fabricated in which the n-type layer 35 was formed with differing V/III ratio, which is a ratio of a flow rate of ammonia constituting a compound containing a group V element to a flow rate of TMG, TMA constituting a compound containing a group III element. At that time, by allowing the flow rate of TES to differ, verification elements 2A having the n-type layer 35 exhibiting different Si-doping concentrations were fabricated.

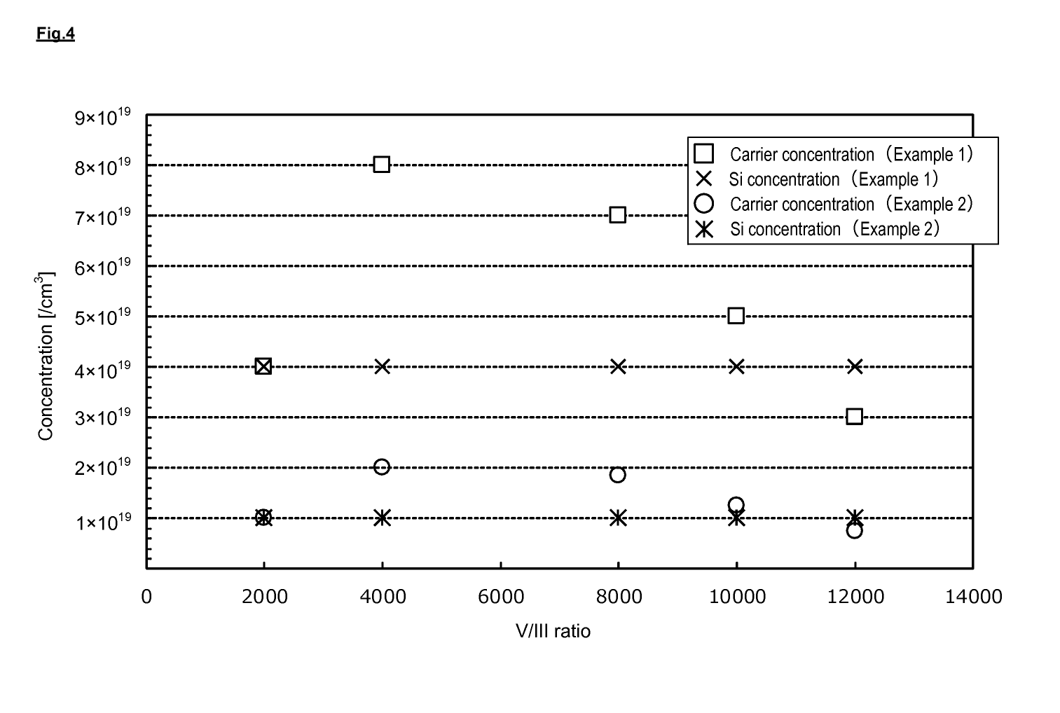

FIG. 4 is a graph showing a relationship of the V/III ratio to the Si concentration and the carrier concentration of the n-type layer 35 of the verification elements 2A when the verification elements are fabricated while changing the V/III ratio. Here, the Si concentration of the n-type layer 35 was measured by the SIMS (Secondary Ion Mass Spectrometry: secondary ion mass spectroscopy), and the carrier concentration was measured by using a Hall measurement apparatus.

### EXAMPLE 1

Five kinds of verification elements 2A were formed by setting the Si-doping concentration to be 4×10¹⁹/cm³ and setting the V/III ratio to be 2000, 4000, 8000, 10000, and 12000 as conditions for growth of the n-type layer 35.

### EXAMPLE 2

Five kinds of verification elements 2A were formed by setting the Si-doping concentration to be 1×10¹⁹/cm³ and setting the V/III ratio to be 2000, 4000, 8000, 10000, and 12000 as conditions for growth of the n-type layer 35.

According to Example 1 in which the Si-doping concentration of the n-type layer 35 is set to be 4×10¹⁹/cm³, the Si concentration and the carrier concentration of the n-type layer 35 are approximately the same when the n-type layer 35 is grown by setting the V/III ratio to be 2000. Further, when the V/III ratio is 4000, the carrier concentration is 8×10¹⁹/cm³, which is a double of the Si concentration. When the V/III ratio is 8000, the carrier concentration is 7×10¹⁹/cm³, which is close to a double of the Si concentration, though the carrier concentration is lower as compared with the case in which the V/III ratio is 4000. When the V/III ratio is 10000, the carrier concentration is 5×10¹⁹/cm³, which is still higher than the Si concentration, though the carrier concentration is decreased as compared with the case in which the V/III ratio is 8000. On the other hand, when the V/III ratio is 12000, the carrier concentration is 3×10¹⁹/cm³, which is lower than the Si concentration.

In Example 2 in which the Si-doping concentration of the n-type layer 35 is set to be 1×10¹⁹/cm³ as well, tendency of the carrier concentration is the same as that of Example 1. In other words, when the n-type layer 35 is grown by setting the V/III ratio to be 2000, the Si concentration and the carrier concentration of the n-type layer 35 are approximately the same. When the V/III ratio is 4000, the carrier concentration is 2×10¹⁹/cm³, which is extremely higher than the Si concentration. When the V/III ratio is 8000 or 10000, the carrier concentration is still higher than the Si concentration, though the carrier concentration is lower as compared with the case in which the V/III ratio is 4000. On the other hand, when the V/III ratio is 12000, the carrier concentration is lower than the Si concentration.

According to the results shown in FIG. 4, it will be understood that the n-type layer 35 is formed to have a carrier concentration higher than the Si concentration thereof when the V/III ratio is set to be higher than 2000 and not higher than 10000 as conditions for growth of the n-type layer 35 irrespective of the value of the Si concentration. In particular, when the V/III ratio is set to be 4000, the n-type layer 35 is formed to have a carrier concentration extremely higher than the Si concentration thereof. This allows that, even if the n-type layer 35 is not doped with Si at an extremely high concentration, a high carrier concentration is achieved to reduce the resistance of the n-type layer 35 by setting the V/III ratio to be higher than 2000 and not higher than 10000 in growing the n-type layer 35.

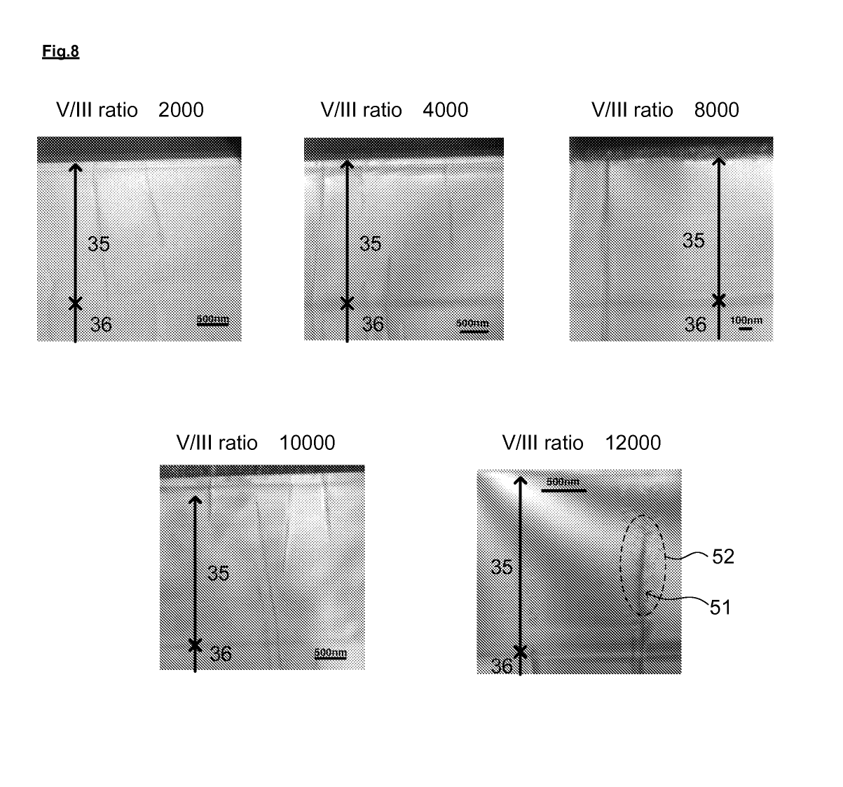

Here, when the V/III ratio is set to have an extremely high value such as 12000, the carrier concentration formed in the n-type layer 35 is lower than the dopant Si concentration. This is presumed to be due to the following reason. In a growing process, the n-type layer 35 grows depending on a balance between etching and growth. When the V/III ratio is set to be too high, the etching becomes strong, so that crystal defects are generated thereby to inactivate the carriers. Here, the generation of this phenomenon will be described later with reference to sectional photographs of the n-type layer 35 shown in FIG. 8.

### [Verification of I-V Characteristics, Light Emitting Characteristics]

Next, with reference to Examples, description will be given on a fact that an electric current needed for light emission can be let to flow through the element at a low operation voltage by growing the n-type layer 35 to form the element with the V/III ratio being set to be higher than 2000 and not higher than 10000.

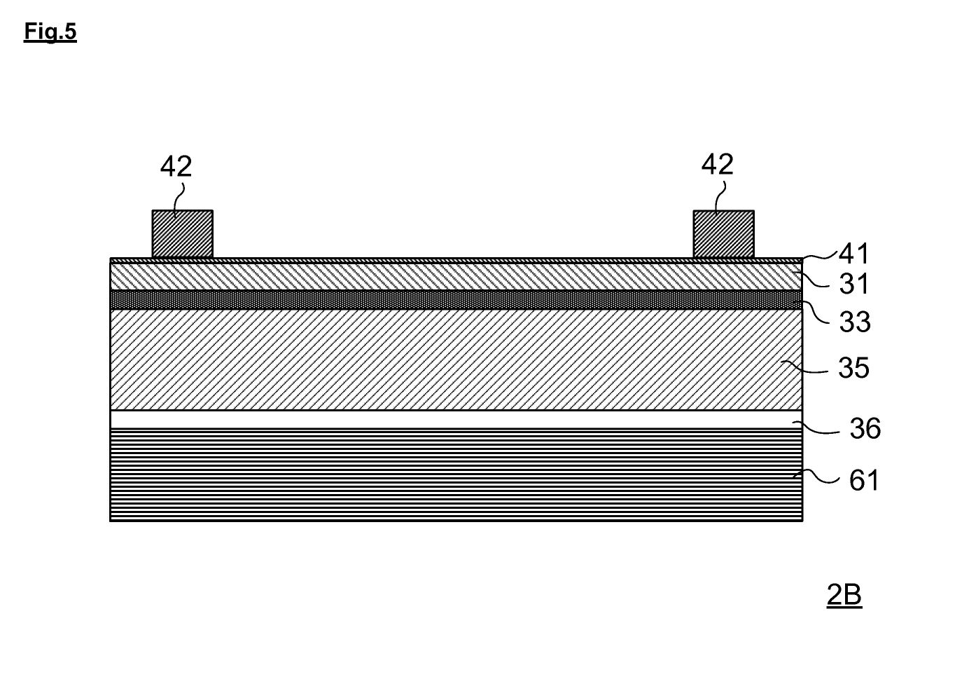

FIG. 5 shows an example of a verification element for verifying the I-V characteristics and the light emitting characteristics. The verification element 2B shown in FIG. 5 is constructed in such a manner that a light emitting layer 33, a p-type layer 31, and a p⁺ layer 41 are further formed on an upper surface of the n-type layer 35 of the verification element 2A shown in FIG. 3, and power supply terminals 42 are formed at two sites on an upper surface of the p⁺ layer 41. The p⁺ layer 41 is formed so as to reduce the contact resistance between the p-type layer 31 and the power supply terminals 42. Here, the p⁺ layer 41 is constituted of p-GaN that is doped at a high concentration.

Further, five kinds of verification elements 2B were formed by setting the Si-doping concentration to be 4×10¹⁹/cm³ and setting the V/III ratio to be 2000, 4000, 8000, 10000, and 12000 as conditions for growth of the n-type layer 35.

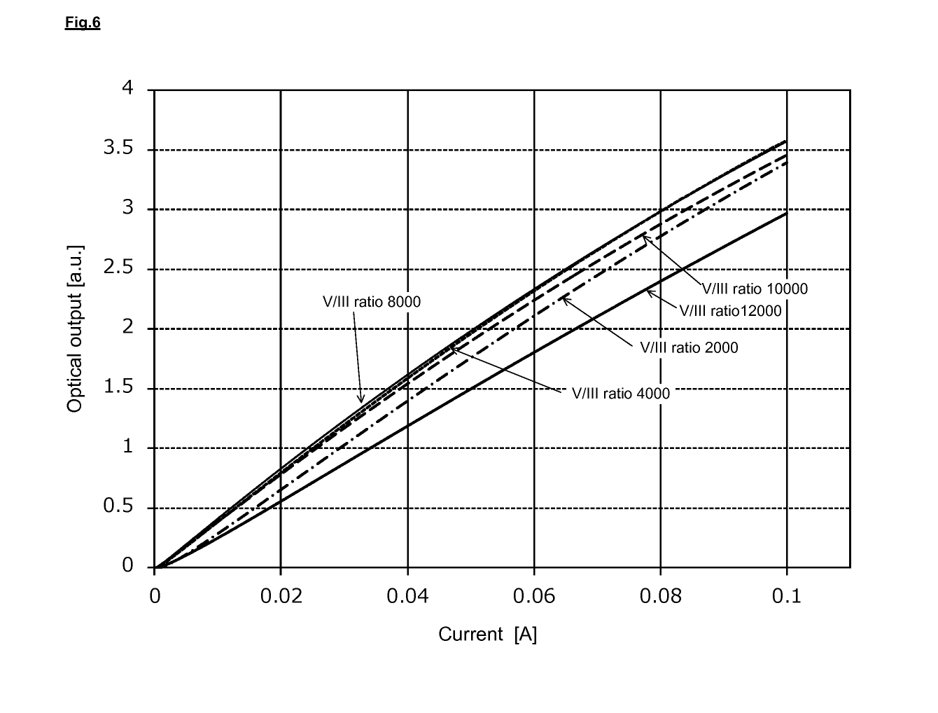

FIG. 6 is a graph showing a relationship of electric current-light emission output when an electric current is applied to each verification element 2B with differing V/III ratio at the time of forming the n-type layer 35.

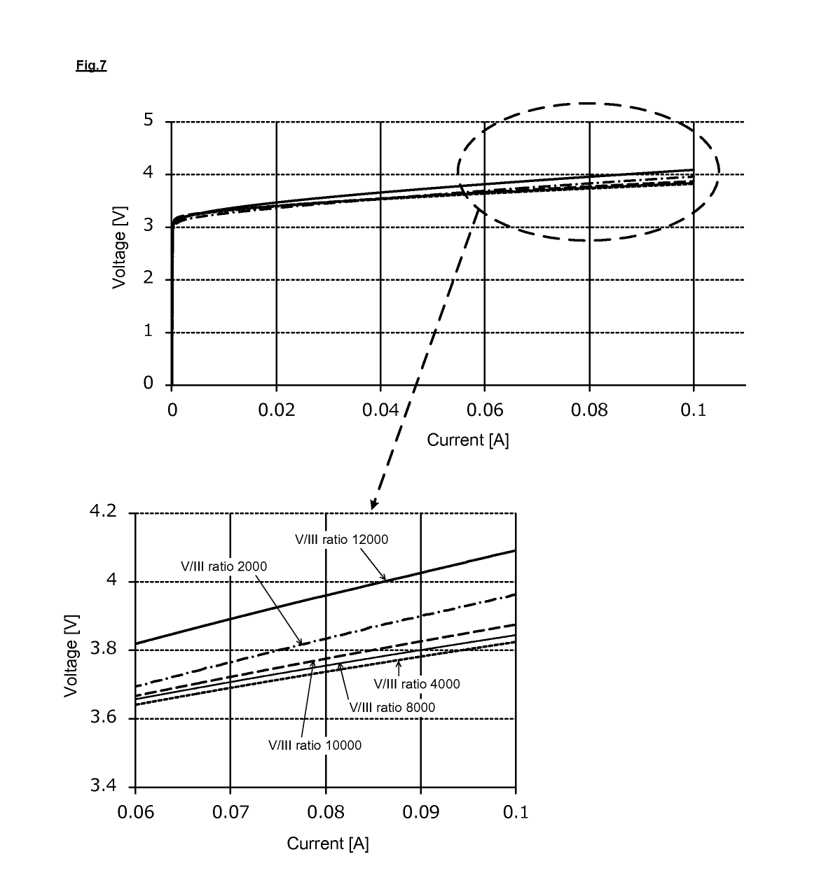

Also, FIG. 7 is a graph showing the I-V characteristics when a voltage is applied to each verification element 2B with differing V/III ratio at the time of forming the n-type layer 35. For each verification element 2B, a relationship of the electric current I that flows when a voltage V is applied to the power supply terminals 42 is made into a graph.

According to FIG. 6, it will be understood that, in the verification element 2B in which the n-type layer 35 has been formed by setting the V/III ratio to be 4000, 8000, or 10000, the light emission output obtained when the same electric current flows is high as compared with the verification element 2B in which the n-type layer 35 has been formed by setting the V/III ratio to be 2000 or 12000. Also, according to FIG. 7, it will be understood that, in the verification element 2B in which the n-type layer 35 has been formed by setting the V/III ratio to be 4000, 8000, or 10000, the voltage needed for the same electric current to flow is suppressed to be low as compared with the verification element 2B in which the n-type layer 35 has been formed by setting the V/III ratio to be 2000 or 12000.

From the results of FIGS. 6 and 7 also, it will be understood that the resistance of the n-type layer 35 is reduced by growing the n-type layer 35 with the V/III ratio being set to be higher than 2000 and not higher than 10000. In other words, by forming the nitride light emitting element 1 including the n-type layer 35 formed with the V/III ratio being set to be higher than 2000 and not higher than 10000, the needed amount of electric current can be let to flow at a low operation voltage, and the amount of light emission obtained when the same amount of electric current is supplied can be improved. In other words, the light emission efficiency can be improved without raising the Si-doping concentration into the n-type layer 35 to be considerably high.

### [Verification of Upper Limit Value of V/III Ratio]

As described before with reference to FIG. 4, when the V/III ratio is set to have an extremely high value such as 12000, the carrier concentration formed in the n-type layer 35 is lower than the dopant Si concentration. This seems to be because crystal defects have been formed in the n-type layer 35. This will be described with reference to sectional TEM (Transmission Electron Microscope: transmission-type electron microscope) photographs of the n-type layer 35 shown in FIG. 8.

FIG. 8 is a sectional TEM photograph of the n-type layer 35 in five kinds of verification elements 2A (See FIG. 3) in which the n-type layer 35 has been grown while setting the V/III ratio to be 2000, 4000, 8000, 10000, and 12000 in the verification elements 2A shown in FIG. 3. According to FIG. 8, it is confirmed that, when the V/III ratio is set to be 12000, crystal defects 52 are generated in the surroundings of a threading dislocation 51 formed from the undoped layer 36 to the n-type layer 35. In contrast, when the V/III ratio is set to be 2000, 4000, 8000, or 10000, crystal defects 52 such as these are not confirmed.

It seems that, when the V/III ratio is set to be 12000, inactivation of the dopant Si has occurred because the crystal defects 52 have been formed in the n-type layer 35. This seems to have raised the resistance of the n-type layer 35 and increased the non-radiative recombination center due to the crystal defects 52, leading to decrease in the light emission efficiency.

From the TEM photograph of FIG. 8 and the graph of FIG. 4, it will be understood that, when the V/III ratio at the time of forming the n-type layer 35 is raised to be too high, the carrier concentration comes to be lower than the dopant Si concentration because of the inactivation of Si due to generation of the crystal defects 52. Therefore, the upper limit value of the V/III ratio at the time of forming the n-type layer 35 is preferably a value such that the crystal defects 52 are not generated. According to FIGS. 4 and 8, it will be understood that, at least in the case in which the V/III ratio at the time of forming the n-type layer 35 is 10000, generation of crystal defects 52 is not confirmed, and the n-type layer 35 is formed to have a carrier concentration higher than the Si concentration. Therefore, the V/III ratio at the time of forming the n-type layer 35 is preferably set to be not higher than 10000.

Also, from FIG. 4, it will be understood that, in the case in which the V/III ratio at the time of forming the n-type layer 35 is set to be 2000, the Si concentration and the carrier concentration are almost equivalent to each other, and that, in the case in which the V/III ratio is set to be 4000, 8000, or 10000, the n-type layer 35 is formed to have a carrier concentration higher than the Si concentration. From this, it will be understood that, at least by setting the V/III ratio at the time of forming the n-type layer 35 to be higher than 2000 and not higher than 10000, the n-type layer 35 is formed to have a carrier concentration higher than the Si concentration.

### [Manufacturing Method]

Next, one example of a method for manufacturing the nitride light emitting element 1 will be described. Here, the production conditions and the dimensions such as the film thickness in the following description of the manufacturing method are merely examples, so that the present invention is not limited to these numerical values.

### (Step S1)

An LED epi-layer is formed on a sapphire substrate. This step is carried out, for example, by the following procedure.

### <Preparation of Sapphire Substrate>

First, cleaning of a c-plane sapphire substrate is carried out. More specifically, this cleaning is carried out, for example, by placing the c-plane sapphire substrate in a processing furnace of an MOCVD apparatus and raising the temperature within the furnace to be, for example, 1150° C. while allowing a hydrogen gas to flow at a flow rate of 10 slm in the processing furnace.

### <Forming Undoped Layer>

Next, a low-temperature buffer layer made of GaN is formed on the surface of the c-plane sapphire substrate, and further an underlayer made of GaN is formed on top thereof. The low-temperature buffer layer and the underlayer correspond to the undoped layer.

A more specific method of forming the undoped layer is, for example, as follows. First, the pressure within the furnace of the MOCVD apparatus is set to be 100 kPa, and the temperature within the furnace is set to be 480° C. Then, TMG having a flow rate of 50 μmol/min and ammonia having a flow rate of 250000 μmol/min are supplied as source material gases for 68 seconds into the processing furnace while allowing a nitrogen gas and a hydrogen gas each having a flow rate of 5 slm to flow as carrier gases in the processing furnace. By this process, the low-temperature buffer layer made of GaN and having a thickness of 20 nm is formed on the surface of the c-plane sapphire substrate.

Next, the temperature within the furnace of the MOCVD apparatus is raised to 1150° C. Then, TMG having a flow rate of 100 μmol/min and ammonia having a flow rate of 250000 μmol/min are supplied as source material gases for 30 minutes into the processing furnace while allowing a nitrogen gas having a flow rate of 20 slm and a hydrogen gas having a flow rate of 15 slm to flow as carrier gases in the processing furnace. By this process, the underlayer made of GaN and having a thickness of 1.7 μm is formed on the surface of the low-temperature buffer layer.

<Forming n-type Layer 35>

Next, the n-type layer 35 having a composition of AlₓGa₁₋ₓN (0<x≦1) is formed on top of the undoped layer. Here, a protective layer made of n-type GaN may be formed on top thereof in accordance with the needs.

A more specific method of forming the n-type layer 35 is, for example, as follows. First, the pressure within the furnace of the MOCVD apparatus is set to be 30 kPa. Then, TMG, TMA, and ammonia are supplied as source material gases into the processing furnace under conditions such that the V/III ratio, which is the ratio of the flow rate of ammonia constituting the compound containing a group V element to the flow rate of TMG and TMA constituting the compounds containing a group III element, comes to be higher than 2000 and not higher than 10000 while allowing a nitrogen gas having a flow rate of 20 slm and a hydrogen gas having a flow rate of 15 slm to flow as carrier gases in the processing furnace, and TES having a flow rate corresponding to the concentration of Si with which the n-type layer 35 is to be doped is supplied into the processing furnace.

For example, by supplying TMG having a flow rate of 50 μmol/min, TMA having a flow rate of 3 μmol/min, ammonia having a flow rate of 220000 μmol/min, and TES having a flow rate of 0.045 μmol/min for 30 minutes into the processing furnace, a high-concentration electron supply layer having a composition of Al_{0.06}Ga_{0.94}N with a V/III ratio of 4000, a dopant Si concentration of 4×10¹⁹/cm³, and a thickness of 500 nm is formed on top of the undoped layer.

As described above, the n-type layer 35 is grown by setting the V/III ratio, which is the ratio of the flow rate of ammonia constituting the compound containing a group V element to the flow rate of TMG and TMA constituting the compounds containing a group III element, to be higher than 2000 and not higher than 10000. By this process, the n-type layer 35 is formed to have a carrier concentration higher than the dopant Si concentration.

In the case of forming the protective layer made of GaN, the supply of TMA is stopped thereafter, and the other source material gases are supplied for 6 seconds, whereby the protective layer made of n-type GaN and having a thickness of 5 nm is formed on top of the electron supply layer.

### <Forming Light Emitting Layer 33>

Next, a light emitting layer 33 having a multiquantum well structure in which a well layer constituted of InGaN and a barrier layer constituted of AlGaN are periodically repeated is formed on top of the n-type layer 35.

A more specific method of forming the light emitting layer 33 is, for example, as follows. First, the pressure within the furnace of the MOCVD apparatus is set to be 100 kPa, and the temperature within the furnace is set to be 830° C. Then, a step of supplying TMG having a flow rate of 10 μmol/min, TMI (trimethylindium) having a flow rate of 12 μmol/min, and ammonia having a flow rate of 300000 μmol/min as source material gases for 48 seconds into the processing furnace is carried out while allowing a nitrogen gas having a flow rate of 15 slm and a hydrogen gas having a flow rate of 1 slm to flow as carrier gases in the processing furnace. Thereafter, a step of supplying TMG having a flow rate of 10 μmol/min, TMA having a flow rate of 1.6 μmol/min, TES having a flow rate of 0.002 μmol/min, and ammonia having a flow rate of 300000 μmol/min for 120 seconds into the processing furnace is carried out. Thereafter, by repeating these two steps, the light emitting layer 33 having a multiquantum well structure of 15 periods by the well layer made of InGaN having a thickness of 2 nm and the barrier layer made of AlGaN having a thickness of 7 nm is formed on the surface of the n-type layer 35.

<Forming p-type Layer 31>

Next, a layer (hole supply layer) constituted of Al_{y}Ga_{1-y}N (0<y≦1) is formed on top of the light emitting layer 33. Further, a layer (protective layer) constituted of GaN is formed on top thereof. The hole supply layer and the protective layer correspond to the p-type layer 31.

A more specific method of forming the p-type layer 31 is, for example, as follows. First, the pressure within the furnace of the MOCVD apparatus is maintained to be 100 kPa, and the temperature within the furnace is raised to 1050° C. while allowing a nitrogen gas having a flow rate of 15 slm and a hydrogen gas having a flow rate of 25 slm to flow as carrier gases in the processing furnace. Thereafter, TMG having a flow rate of 35 μmol/min, TMA having a flow rate of 20 μmol/min, ammonia having a flow rate of 250000 μmol/min, and biscyclopentadienyl having a flow rate of 0.1 μmol/min are supplied as source material gases for 60 seconds into the processing furnace. By this process, a hole supply layer having a composition of Al_{0.3}Ga_{0.7}N and having a thickness of 20 nm is formed on the surface of the light emitting layer 33. Thereafter, by changing the flow rate of TMA to 9 μmol/min and supplying the source material gases for 360 seconds, a hole supply layer having a composition of Al_{0.13}Ga_{0.87}N and having a thickness of 120 nm is formed.

Further thereafter, the supply of TMA is stopped, and then, by changing the flow rate of biscyclopentadienyl to 0.2 μmol/min and supplying the source material gases for 20 seconds, a contact layer made of p-type GaN having a thickness of 5 nm is formed.

Here, magnesium (Mg), beryllium (Be), zinc (Zn), carbon (C), and others may be used as the p-type impurity.

In this manner, the LED epi-layer made of the undoped layer, the n-type layer 35, the light emitting layer 33, and the p-type layer 31 is formed on the sapphire substrate.

### (Step S2)

Next, an activation process is carried out on the wafer obtained in the step 51. More specifically, an activation process of 15 minutes at 650° C. in a nitrogen atmosphere is carried out using an RTA (Rapid Thermal Anneal: rapid heating) apparatus.

### (Step S3)

Next, an insulating layer 21 is formed at predetermined sites on top of the p-type layer 31. More specifically, the insulating layer 21 is preferably formed at sites located below the region where the power supply terminal 42 will be formed in a later step. As the insulating layer 21, film of SiO₂, for example, is formed to a thickness of about 200 nm. Here, it is sufficient that the material for forming the film is an insulating material, and the material may be, for example, SiN, Al₂O₃, or the like.

### (Step S4)

An electroconductive layer 20 is formed to cover the upper surface of the p-type layer 31 and the insulating layer 21. Here, the electroconductive layer 20 having a multilayer structure including a reflection electrode 19, a protective layer 17, and a solder layer 15 is formed.

A more specific method for forming the electroconductive layer 20 is, for example, as follows. First, film of Ni having a thickness of 0.7 nm and film of Ag having a thickness of 120 nm are formed over the whole surface so as to cover the upper surface of the p-type layer 31 and the insulating layer 21 by using a sputtering apparatus, thereby to form the reflection electrode 19. Next, contact annealing at 400° C. for 2 minutes is carried out in a dry air atmosphere using an RTA apparatus.

Next, film of Ti having a thickness of 100 nm and film of Pt having a thickness of 200 nm are formed for 3 periods on the upper surface (Ag surface) of the reflection electrode 19 using an electron beam vapor deposition apparatus (EB apparatus), thereby to form the protective layer 17. Further thereafter, Ti having a thickness of 10 nm is vapor-deposited on the upper surface (Pt surface) of the protective layer 17, and thereafter Au—Sn solder made of 80% of Au and 20% of Sn is vapor-deposited to a thickness of 3 μm, thereby to form the solder layer 15.

Here, in this step of forming the solder layer 15, a solder layer may be also formed on an upper surface of a support substrate 11 that is prepared separately from the sapphire substrate. This solder layer may be made of the same material as the solder layer 15. Here, as described before in the section of structure, CuW, for example, is used as this support substrate 11.

### (Step S5)

Next, the sapphire substrate and the support substrate 11 are bonded to each other. More specifically, the solder layer 15 and the support substrate 11 are bonded to each other at a temperature of 280° C. and under a pressure of 0.2 MPa.

### (Step S6)

Next, the sapphire substrate is exfoliated. More specifically, KrF excimer laser is radiated from the sapphire substrate side in a state in which the sapphire substrate is facing upward and the support substrate 11 is facing downward, so as to exfoliate the sapphire substrate by decomposing the interface between the sapphire substrate and the LED epi-layer. While laser passes through sapphire, GaN (undoped layer) located therebelow absorbs laser, so that this interface comes to have a high temperature to decompose GaN. This exfoliates the sapphire substrate.

Thereafter, GaN (undoped layer) remaining on the wafer is removed by wet etching using hydrochloric acid or the like or by dry etching using an ICP apparatus, so as to expose the n-type layer 35.

### (Step S7)

Next, adjacent elements are separated from each other. More specifically, with respect to a boundary region to an adjacent element, the LED layer 30 is etched using an ICP apparatus until the upper surface of the insulating layer 21 is exposed. This separates the LED layers 30 of adjacent regions from each other. Here, during this time, the insulating layer 21 functions as an etching stopper layer.

Here, in this etching step, it is preferable that the element side surface is made to be an inclined surface having a taper angle of 10° or more instead of being vertical. This allows that an insulating layer is more likely to adhere to the side surface of the LED layer 30 when the insulating layer is formed in a later step, whereby electric current leakage can be prevented.

Also, after the step S7, an uneven undulating surface may be formed on the upper surface of the LED layer 30 by using an alkali solution such as KOH. This increases the light extraction area and can improve the light extraction efficiency.

### (Step S8)

Next, a power supply terminal 42 is formed on the upper surface of the n-type 35. More specifically, after forming the power supply terminal 42 made of Ni having a film thickness of 10 nm and Au having a film thickness of 10 nm, sintering is carried out at 250° C. for 1 minute in a nitrogen atmosphere.

As subsequent steps, the upper surface of the element other than the exposed element side surface and the power supply terminal 42 is covered with an insulating layer. More specifically, an SiO₂ film is formed using an EB apparatus. Here, an SiN film may be formed as well. Further, the elements are separated from each other using, for example, a laser dicing apparatus; the back surface of the support substrate 11 is joined to a package using, for example, an Ag paste; and wire bonding is carried out on the power supply terminal 42.

### [Other Embodiments]

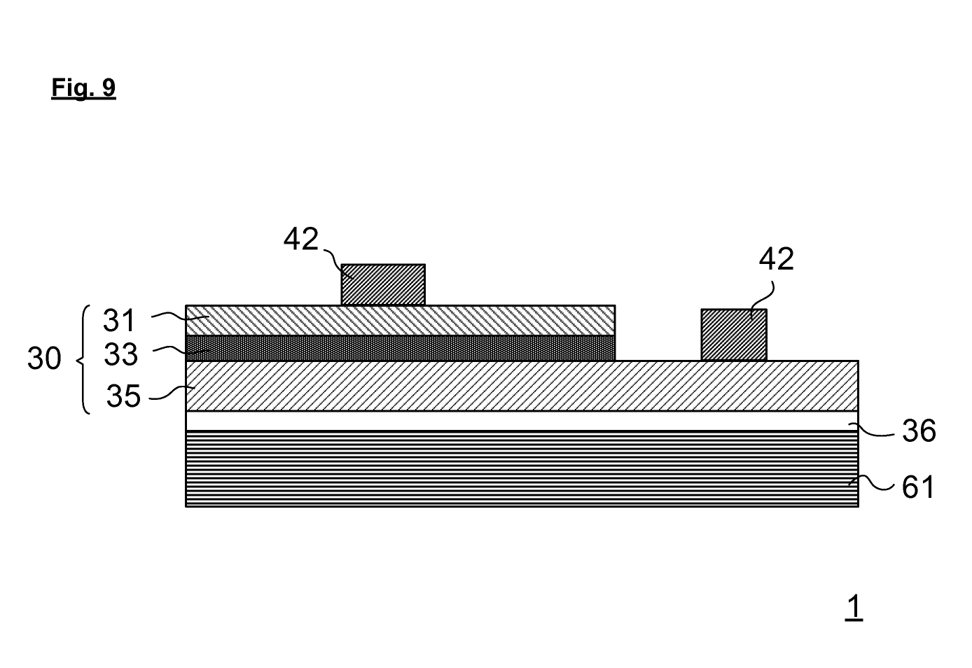

Hereafter, other embodiments will be described.

<1> In FIG. 1, description has been given assuming that the nitride light emitting element 1 is an LED element having what is known as a longitudinal-type structure; however, referring to FIG. 9, the nitride light emitting element 1 may be achieved as an LED element having a lateral-type structure.

The nitride light emitting element 1 shown in FIG. 9 is constructed by having an undoped layer 36 on a sapphire substrate 61 and stacking an n-type layer 35, a light emitting layer 33, and a p-type layer 31 on top thereof in this order from below. A part of the upper surface of the n-type layer 35 is exposed, and power supply terminals 42 are formed on top of this exposed surface of the n-type layer 35 and on the upper surface of the p-type layer 31.

According to this construction as well, the n-type layer 35 is achieved to have a carrier concentration higher than the dopant Si concentration by growing AlₓGa₁₋ₓN with the V/III ratio being set to be higher than 2000 and not higher than 10000 to form the n-type layer 35, so that reduction of the element resistance is achieved, and an effect similar to that of the above-described longitudinal-type nitride light emitting element 1 is produced.

In forming the nitride light emitting element 1 shown in FIG. 9, after the above-described steps 51 to S2, etching is carried out from the p-type layer 31 side until a part of the upper surface of the n-type layer 35 is exposed. Thereafter, power supply terminals 42 are formed by performing a process similar to that of the step S8 on the upper surface of the p-type layer 31 and on the part of the upper surface of the n-type layer 35.

Here, in the nitride light emitting element 1 of FIG. 9, the reflection electrode 19 may be formed on the back surface side of the sapphire substrate 61. Also, an insulating layer may be formed to cover the upper surface of the LED layer 30 excluding the upper surface of the power supply terminals 42 and to cover the side surface of the LED layer 30.

<2> The structure shown in FIG. 1 and the manufacturing method described above are examples of preferable embodiments, so that there is no need to provide all of these constructions and processes.

For example, the solder layer 15 is formed for efficiently performing the bonding of two substrates, so that the solder layer 15 is not necessarily needed in achieving the function of the nitride light emitting element 1 as long as the bonding of the two substrates can be achieved.

The reflection electrode 19 is preferably provided from the viewpoint of further improving the extraction efficiency of the light radiated from the light emitting layer 33; however, there is not necessarily a need to provide the reflection electrode 19. The same applies to the protective layer 17 and the like as well.

Also, the insulating layer 21 is formed to function as an etching stopper layer at the time of element separation in the step S7; however, there is not necessarily a need to provide the insulating layer 21. However, by forming the insulating layer 21 at a position that opposes the power supply terminal 42 in a direction perpendicular to the substrate surface of the support substrate 11, an effect of widening the electric current in a direction parallel to the substrate surface of the support substrate 11 can be expected.

### DESCRIPTION OF REFERENCE SIGNS

1: Nitride light emitting element
2A: Verification element
2B: Verification element
11: Support substrate
15: Solder layer
17: Protective layer
19: Reflection electrode
20: Electroconductive layer
21: Insulating layer
30: LED layer
31: p-type layer
33: Light emitting layer
35: n-type layer (AlₓGa₁₋ₓN)
36: Undoped layer
41: p⁺-layer
42: Power supply terminal
51: Threading dislocation
52: Crystal defects
61: Sapphire substrate

1. A nitride light emitting element having, on a support substrate, an n-type layer, a p-type layer, and a light emitting layer formed at a position interposed between the n-type layer and the p-type layer,
wherein the n-type layer is constituted of AlₓGa₁₋ₓN (0<x≦1) having a carrier concentration higher than a dopant Si concentration thereof.

2. The nitride light emitting element according to claim 1, wherein the n-type layer is constituted of AlₓGa₁₋ₓN (0<x≦1) having the dopant Si concentration not lower than 1×10¹⁹/cm³.

3. (canceled)

4. A method for manufacturing the nitride light emitting element, having on a support substrate, an n-type layer, a p-type layer, and a light emitting layer formed at a position interposed between the n-type layer and the p-type layer, wherein the n-type layer is constituted of AlₓGa₁₋ₓN (0<x≦1) having a carrier concentration higher than a dopant Si concentration thereof, comprising:
a step of forming the n-type layer by supplying, into a processing furnace, a source material gas wherein a V/III ratio, which is a ratio of a flow rate of a compound containing a group V element to a flow rate of a compound containing a group III element, is larger than 2000 and not larger than 10000, for crystal growth.

5. The method for producing an LED element according to claim 4, wherein the n-type layer is constituted of AlₓGa₁₋ₓN (0<x≦1) having the dopant Si concentration not lower than 1×10¹⁹/cm³.
